(19) United States
(12) Patent Application Publication
(10) Pub. No.: US 2002/0110979 A1
(43) Pub. Date: Aug. 15, 2002

(54) METHOD FOR FORMING A DRAM CONTACT PLUG

(76) Inventor: Chuan Fu Wang, San-Chung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/779,485

(22) Filed: Feb. 9, 2001

(51) Int. Cl. H01L 21/8242

(52) U.S. Cl. 438/248

(57) ABSTRACT

The present invention provides a method of forming a DRAM contact plug. Multiple word lines are formed on the substrate to divide the active area into at least one bit line contact area and one node contact area. Multiple poly landing pads are then formed between the multiple word lines. The spacers and poly landing pads between the word lines outside the active area are removed thereafter. A dielectric layer is then formed to cover both the word lines and poly landing pads as well as to fill the spaces between the word lines outside the active area. Finally, a bit line contact plug and a node contact plug, both electrically connecting to the poly landing pads, are formed in each bit line contact plug hole and node contact plug hole, respectively.

### BACKGROUND OF THE INVENTION

1. Field of the invention

The present invention relates to a method of forming a DRAM contact plug.

2. Description of the Prior Art

A dynamic random access memory (DRAM) comprises numerous memory cells, each of which comprises a metal oxide semiconductor (MOS) and one or two capacitors. Each MOS and capacitor link with bit-lines through word lines to determine the location of each memory cell.

Please refer to FIG. 1 to FIG. 5 of the cross-sectional views of the method of forming a DRAM contact plug according to the prior art. As shown in FIG. 1 and FIG. 2 of the top view and the sectional view of the DRAM, respectively, a substrate 10 has at least one active area 12 isolated by shallow trench isolations (STI). Multiple word lines 14, each word line having both a cap layer 16 on its top surface and a spacer 18 on either of its sides, are formed on the surface of the substrate 10. Generally, the cap layer 16 and the spacer 18 are composed of silicon nitride and silicon oxide, respectively. The method of forming the word lines 14 comprises a chemical vapor deposition (CVD), followed by lithographic and etching processes. As shown in FIG. 1, the multiple word lines 14 divide the active area 12 into at least one bit line contact area 20 and one node contact area 22.

As shown in FIG. 3, a dielectric layer 24 is formed to cover the word lines 14, cap layer 16 and spacers 18 as well as to fill the spaces between the word lines 14 outside the active area 12. As shown in FIG. 4 and FIG. 5, a bit line contact plug hole 26 and a node contact plug hole 28 are formed from the dielectric layer 24 through the underlying bit line contact area 20 and node contact area 22, respectively, to the surface of the substrate 10. Finally, a bit line contact plug 26a and a node contact plug 28a are formed in each bit line contact plug hole 26 and node contact plug hole 28, respectively.

The trend to increase integration of the DRAM has been to produce semiconductors with smaller line widths. Thus, the ratio of the thickness of the spacer 18 to the width of the space between two word lines 14 is also relatively increased. As a result, voids are formed during the filling process of the dielectric layer 24 due to the increase in the relative ratio of the height to the width of the space between the word lines 14. Consequently, since the line width is designed to be less than 0.15 microns, the occurrence of voids seriously reduces product yield rate. The etching process used to etch the dielectric layer 24 down to the surface of the substrate 10 when forming both the bit contact plug hole 26 and the node contact plug hole 28 of the prior art, is a self-aligned contact (SAC) process. Since the line width is less than a certain value, void occurrences occur and lead to an incomplete SAC process to create a defective device.

### SUMMARY OF THE INVENTION

It is therefore a primary object of the present invention to provide a method of forming a DRAM contact plug to prevent the occurrence of voids.

In the present invention, a method of forming a DRAM contact plug is provided. Multiple word lines, each word line having both a cap layer on its top surface and a spacer on either of its side, are formed on the substrate to divide the active area into at least one bit line contact area and one node contact area. Multiple poly landing pads are then formed between the multiple word lines. Both the spacers and poly landing pads between the word lines located outside the active area are removed thereafter. A dielectric layer is formed to cover the word lines and poly landing pads as well as to fill the spaces between the word lines outside the active area. Finally, a bit line contact plug and a node contact plug, both electrically connect to the poly landing pads, are formed in each bit line contact plug hole and node contact plug hole, respectively.

It is an advantage of the present invention over the prior art that the gap-filling ability of the dielectric layer is efficiently increased, especially when the line width of the semiconductor is designed to be less than 0.15 microns. As well, the incomplete etching caused by the SAC process according to the prior art is prevented by the present invention process of forming poly landing pads. As a result, the product yield rate is increased.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWING

FIG. 1 to FIG. 5 are the cross-sectional views of the method of forming a DRAM contact plug according to the prior art.

FIG. 6 to FIG. 11 are the cross-sectional view of the method of forming a DRAM contact plug according to the present invention.

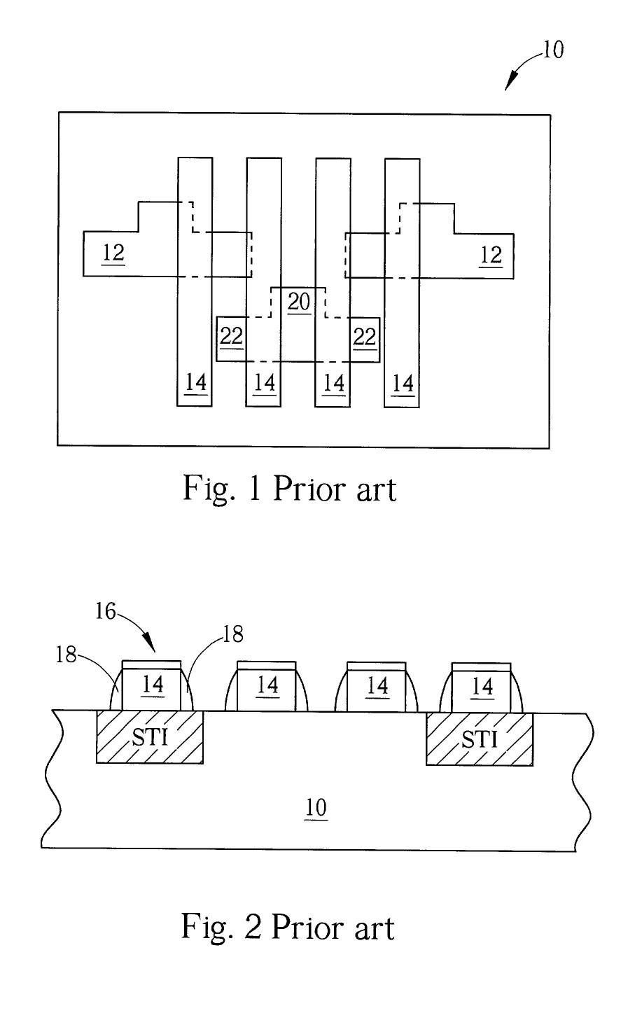

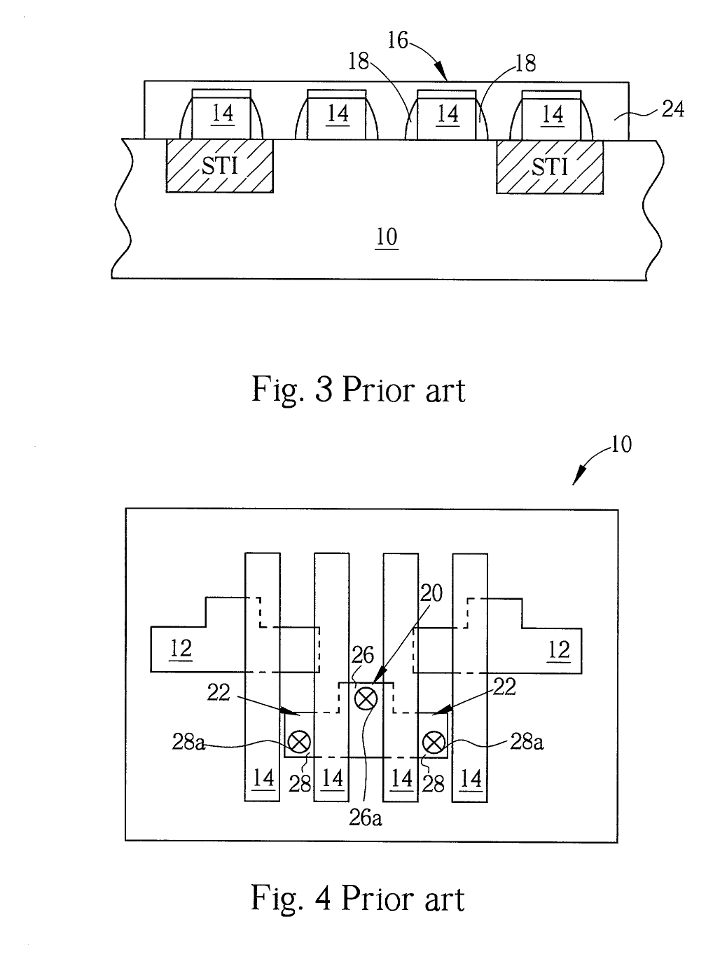

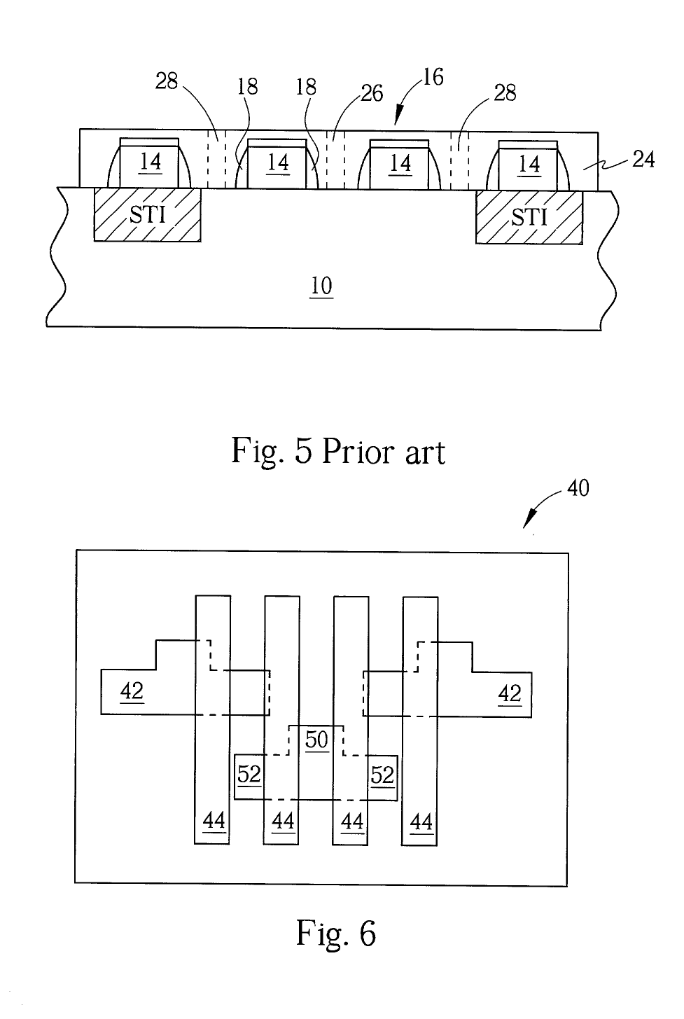

### DETAILED DESCRIPTION OF THE PREFERRED EMBODIMENT

Please refer to FIG. 6 to FIG. 11 of the cross-sectional views of the method of forming a DRAM contact plug according to the present invention. As shown in FIG. 6 of the top view of the DRAM, a substrate 40 has at least one active area 42 isolated by shallow trench isolations (STI). In the preferred embodiment of the present invention, the substrate 40 is a P-type silicon substrate with a <100> bottom surface. The method of the present invention is applied not only to the P-type silicon substrate but also to variants such as a silicon-on-insulator (SOI) substrate of both a P-type silicon layer and an insulator layer (not shown) and formed by a separation by implantation oxygen (SIMOX) process. The method of fabricating the SOI substrate is not the primary concern of the present invention and is omitted in the following discussion.

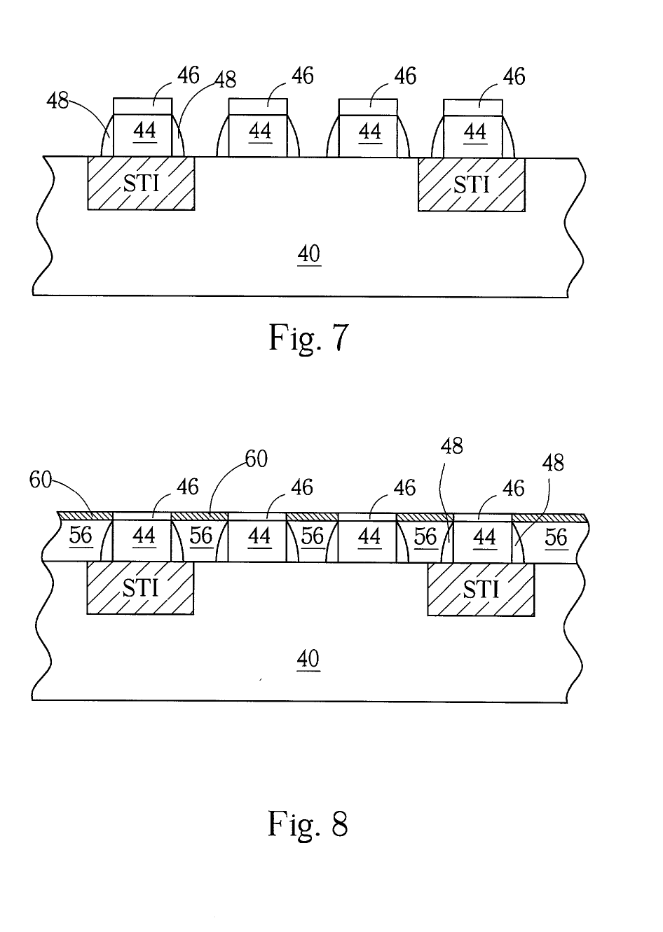

As shown in FIG. 6 and FIG. 7 of the top and sectional views, respectively, of the DRAM, multiple word lines 44, each word line having both a cap layer 46 on its top surface and a spacer 48 on either of its side, are formed on the surface of the substrate 40. The preferred thickness of the cap layer 46, composed of silicon oxide and functioned as both a stop and protective layer of the word line 44 in the subsequent chemical mechanical polishing (CMP) process and spacer 48 etching process, respectively, is approximately 1500 angstroms. As shown in FIG. 6, the multiple word lines 44 divide the active area into at least one bit line contact area 50 and one node contact area 52.

As shown in FIG. 8, a low-pressure chemical vapor deposition (LPCVD) process is then performed. A polysilicon layer (not shown) with a thickness of thousands of angstroms is formed on the surface of both the substrate 40 and the multiple word lines 44 as well as filling in the spaces between the multiple word lines 44. The polysilicon layer is composed of a doped polysilicon formed by an in-situ doping process. A CMP process is performed to remove the polysilicon layer down to the surface of the cap layer 48 of the multiple word lines 44. The remaining portions of the polysilicon layer between the multiple word lines 44 are used as poly landing pads 56. A thermal process is then performed after a metal layer 59, composed of tungsten (W) or titanium (Ti), is formed on the surfaces of the multiple poly landing pads 56. A self-aligned silicide (salicide) layer 60, composed of tungsten silicide (Wsiₓ) or titanium silicide (TiSiₓ), with a thickness between 300 to 1500 angstroms, is thus formed between the metal layer 59 and the poly landing pad 56 to reduce the sheet resistance of the poly landing pad 56. The unreacted portions of the metal layer 59 are removed thereafter.

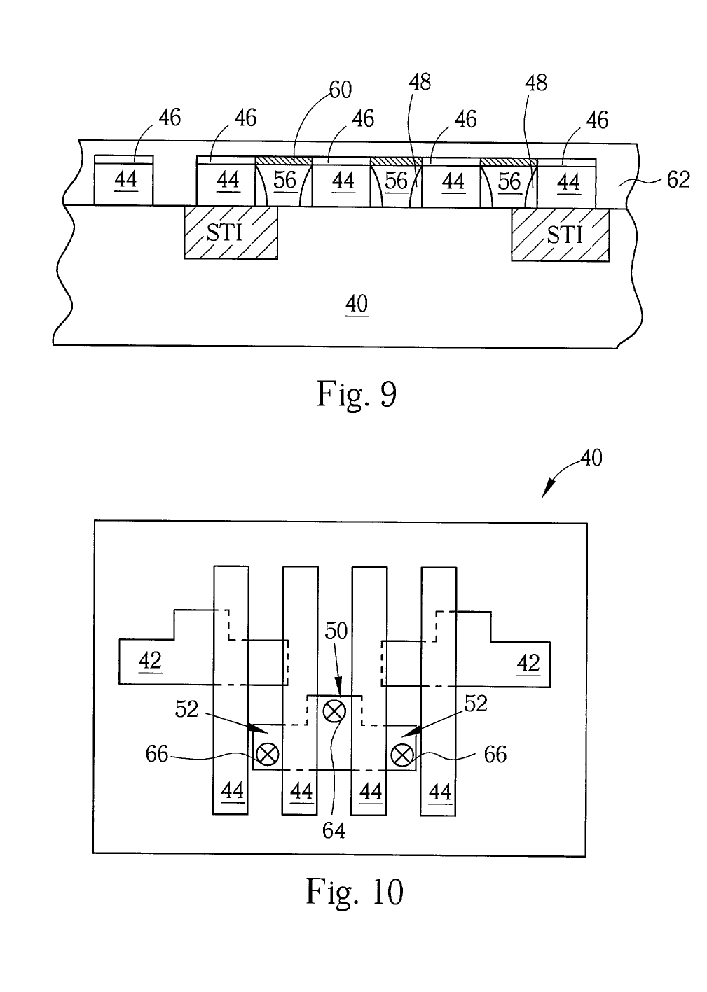

As shown in FIG. 9, after a photoresist layer (not shown) is formed on the surface of the substrate 40, a photo mask pattern is used to remove portions of the photoresist layer outside the active area 42. The photo mask pattern is defined by the reverse photo mask pattern of the active area 42 or that of the union of the active area 42 and the multiple word lines 44, and is used to improve the gap-filling ability of the dielectric layer 62 in a subsequent process. A TCP machine, with a selectivity setting function, is used to perform a first etching process to remove the poly landing pads 56 uncovered by the photoresist layer. A second etching process is then performed to remove the spacers 48 uncovered by the photoresist layer, followed by the removal of the photoresist layer.

A dielectric layer 62 is formed to cover the remaining word lines 44 and poly landing pads 56 as well as to fill the spaces between the word lines 44 outside the active area 42. The dielectric layer 62 can be made of materials with low dielectric constants, such as silicon dioxide (SiO₂), phosphosilicate glass (PSG), borophosphosilicate glass (BPSG), fluorinated silicon dioxide (FₓSiO_{y}), parylene, teflon or amorphous carbon (α-C:F).

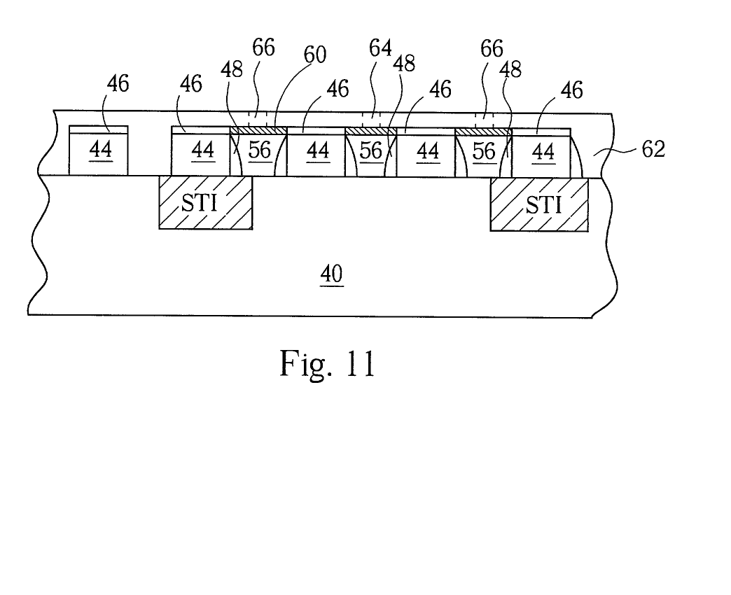

As shown in FIG. 10 and FIG. 11, a bit line contact plug hole and a node contact plug hole (both not shown) are formed through the bit line contact area 50 and the node contact area 52, respectively, to the surface of the poly landing pads 56. Finally, a bit line contact plug 64 and a node contact plug 66, both electrically connected to the poly landing pads 56, are formed in each bit line contact plug hole and node contact plug hole, respectively.

In comparison with the method of forming a DRAM contact plug according to the prior art, the method provided in the present invention comprises an etching process performed to remove spacers 48 on either side of each word line 44 outside the active area 42. The ratio of the height to the width of the space between word lines 44 is thus reduced to prevent void occurrence during the subsequent gap-filling process. The gap-filling ability of the dielectric layer 62, especially when the line width of the semiconductor is designed to be less than 0.15 microns, is also significantly improved. Also, the SAC process according to the prior art is not required in the present invention because of the process of forming poly landing. As a result, the product yield rate is increased.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of forming a DRAM contact plug comprising:
providing a substrate, the substrate comprising at least one active area isolated by shallow trench isolation (STI);
forming multiple word lines, each word line comprising a cap layer on its top surface and a spacer on either side to divide the active area into at least one bit line contact area and one node contact area;
forming multiple poly landing pads between the multiple word lines;
removing the spacers and poly landing pads between the word lines outside the active area;
forming a dielectric layer on the substrate, the dielectric layer covering the word lines and poly landing pads as well as filling the spaces between the word lines outside the active area;
forming a bit line contact plug hole and a node contact plug hole in the dielectric layer through the bit line contact area and the node contact area, respectively, to the surface of the poly landing pads;
forming a bit line contact plug and a node contact plug, electrically connected to the poly landing pads, in each bit line contact plug hole and node contact plug hole, respectively.

2. The method of claim 1 wherein the cap layer, comprising a silicon oxide layer with an underlying silicon nitride layer, is a bilayer structure.

3. The method of claim 1 wherein the method of forming multiple landing pads comprises:
performing a low-pressure chemical vapor deposition (LPCVD) process to form a polysilicon layer covering the multiple word lines and the substrate as well as filling the spaces between the multiple word lines;
performing a chemical mechanical polishing (CMP) process to remove the polysilicon layer down to the surface of the underlying cap layer of the multiple word lines.

4. The method of claim 3 wherein the poly landing pad made from the polysilicon layer, composed of a doped polysilicon formed by an in-situ doping method, has a self-aligned silicide (salicide) layer on its surface to reduce the sheet resistance of the poly landing pad.

5. The method of claim 4 wherein the silicide layer, with a thickness of 300 to 1500 angstroms, is composed of tungsten silicide (Wsiₓ) or titanium silicide (TiSiₓ).

6. The method of claim 4 wherein the method of forming the silicide layer comprises:
forming a metal layer on the surface of the poly landing pad;
performing a thermal process to form the silicide layer between the metal layer and the poly landing pad;
removing the unreacted metal layer.

7. The method of claim 1 wherein the method of removing the spacers and poly landing pads between the word lines outside the active area comprises:
forming a photoresist layer on the surface of a substrate;
removing portions of the photoresist layer outside the active area by using a photomask pattern;
performing a first etching process to remove the poly landing pads uncovered by the photoresist layer;
performing a second etching process to remove the spacers uncovered by the photoresist layer;
removing the photoresist layer.

8. The method of claim 7 wherein the photomask pattern is the reverse photomask pattern of the active area or that of the union of the active area and the multiple word lines.

9. The method of claim 1 wherein the substrate is a silicon substrate or a silicon-on-insulator (SOI) substrate.

10. The method of claim 1 wherein the spacers are composed of silicon nitride.

11. The method of claim 1 wherein the dielectric layer is made of materials with low dielectric constants.

12. A method of forming a DRAM contact plug comprising:
providing a substrate, the substrate comprising at least one active area isolated by shallow trench isolation (STI);
forming multiple word lines, each word line comprising a silicon oxide layer on its top surface and a spacer on either side, to divide the active area into at least one bit line contact area and one node contact area;
performing a LPCVD process to form a polysilicon layer covering the multiple word lines and the substrate as well as filling the spaces between the multiple word lines;
performing a CMP process to remove the polysilicon layer down to the surface of the underlying silicon oxide layer of the multiple word lines in order to form multiple polysilicon landing pads between the multiple word lines;
removing the spacers and poly landing pads between the word lines outside the active area;
forming a dielectric layer on the substrate, the dielectric layer covering the word lines and poly landing pads as well as filling the spaces between the word lines outside the active area;
forming a bit line contact plug hole and a node contact plug hole in the dielectric layer through the bit line contact area and the node contact area, respectively, to the surface of the poly landing pads;
forming a bit line contact plug and a node contact plug, electrically connected to the poly landing pads, in each bit line contact plug hole and node contact plug hole, respectively.

13. The method of claim 12 wherein the poly landing pad made from the poly silicon layer, composed of a doped polysilicon formed by an in-situ doping method, has a salicide layer on the surface to reduce the sheet resistance of the poly landing pad.

14. The method of claim 13 wherein the silicide layer, with a thickness of 300 to 1500 angstroms, is composed of Wsiₓ or TiSiₓ.

15. The method of claim 12 wherein the method of forming the silicide layer comprises:
forming a metal layer on the surface of the poly landing pad;
performing a thermal process to form the silicide layer between the metal layer and the poly landing pad;
removing the unreacted metal layer.

16. The method of claim 12 wherein the dielectric layer is made of silicon dioxide (SiO₂), phosphosilicate glass (PSG), borophosphosilicate glass (BPSG), fluorinated silicon dioxide (FₓSiO_{y}), parylene, teflon or amorphous carbon (α-C:F).

17. The method of claim 1 wherein the method of removing the spacers and poly landing pads between the word lines outside the active area can be performed by a TCP machine with a selectivity setting function.

18. The method of claim 12 wherein the substrate is a silicon substrate or a SOI substrate.

19. The method of claim 12 wherein the spacers are composed of silicon nitride.

20. The method of claim 12 wherein a photomask is defined by the reverse photomask pattern of the active area and used to remove the spacers and poly landing pads between the word lines outside the active area in order to improve the gap-filling ability of the dielectric layer in a subsequent process.
